(19) United States
(12) Patent Application Publication
(10) Pub. No.: US 2025/0102554 A1
(43) Pub. Date: Mar. 27, 2025

(54) METHOD, APPARATUS, AND SYSTEM FOR RISK ASSESSMENT OF AN INSULATION STATE OF ELECTRICAL EQUIPMENT, AND STORAGE MEDIUM

(71) Applicants: WUXI POWER SUPPLY BRANCH OF STATE GRID JIANGSU ELECTRIC POWER CO., LTD., Wuxi, Jiangsu (CN); XI'AN JIAOTONG UNIVERSITY, Xi'an, Shaanxi (CN)

(72) Inventors: Tao ZHANG, Wuxi (CN); Ming REN, Xian (CN); Jin MIAO, Wuxi (CN); Haobin GUAN, Xian (CN); Kai WANG, Xian (CN)

(21) Appl. No.: 18/291,055

(22) PCT Filed: Oct. 11, 2023
(86) PCT No.: PCT/CN2023/123991

§ 371 Date: Jan. 22, 2024

(30) Foreign Application Priority Data
Feb. 17, 2023 (CN) 202310134624.1

(51) Int. Cl. G01R 31/12

(52) U.S. Cl. CPC G01R 31/1272

(57) ABSTRACT

Provided are a method, an apparatus, and a system for risk assessment of an insulation state of electrical equipment and a storage medium. The method includes measuring partial discharge data of electrical equipment using multiple types of sensors, and performing clustering of discharge types; establishing, based on a clustering result of each discharge type, a regression model between sensor response amplitude and apparent discharge energy during a discharge development process; calculating, based on the regression model, the accumulated value of apparent discharge energy of current partial discharge of the electrical equipment, and using the accumulated value as an index of risk assessment to assess an insulation state of the electrical equipment.

### CROSS-REFERENCE TO RELATED APPLICATIONS

This is a national stage application filed under 37 U.S.C. 371 based on International Patent Application No. PCT/CN2023/123991, filed Oct. 11, 2023, which claims priority to Chinese Patent Application No. 202310134624.1 filed with the China National Intellectual Property Administration (CNIPA) on the disclosures of which are incorporated herein by reference in their entireties.

### TECHNICAL FIELD

The present application belongs to the field of electrical equipment insulation and relates to a method, an apparatus, and a system for risk assessment of an insulation state of electrical equipment and a storage medium.

### BACKGROUND

Gas-insulated switchgear (GIS), with advantages such as small space, long maintenance cycle, and convenient transportation and installation, has been widely used at home and abroad since the 1960s. However, a global survey by the International Council on Large Electric Systems (CIGRE) found that the averaged failure rate of GIS with voltage levels above 245 kV averaged is 0.67 times/100 intervals-years and that the failure rate of the State Grid ultra-high voltage is 0.44 times/100 intervals·years, both of which are much higher than the 0.1 times/100 intervals·years recommended by the international electrotechnical commission (IEC). Most of the faults are insulation faults. Internal insulation defects in GIS may cause partial discharge under the action of an electric field. Partial discharge occurs in weak parts of the insulation of electrical equipment under the action of a strong electric field, which is a common situation in high-voltage electrical equipment.

### SUMMARY

The present application provides a method for risk assessment of an insulation state of electrical equipment. The method includes measuring partial discharge data of electrical equipment using multiple types of sensors, and performing clustering of discharge types; establishing, based on a clustering result of each discharge type, a regression model between sensor response amplitude and apparent discharge energy during a discharge development process; calculating, based on the regression model, the accumulated value of apparent discharge energy of current partial discharge of the electrical equipment, and using the accumulated value as an index of risk assessment to assess an insulation state of the electrical equipment.

The present application further provides an apparatus for risk assessment of an insulation state of electrical equipment. The apparatus includes a clustering unit, a modeling unit, and an assessment unit.

The clustering unit is configured to measure partial discharge data of electrical equipment using multiple types of sensors and perform clustering of discharge types.

The modeling unit is configured to establish, based on a clustering result of each discharge type, a regression model between sensor response amplitude and apparent discharge energy during a discharge development process.

The assessment unit is configured to calculate, based on the regression model, the accumulated value of apparent discharge energy of current partial discharge of the electrical equipment and use the accumulated value as an index of risk assessment to assess an insulation state of the electrical equipment.

The present application further provides a system for risk assessment of an insulation state of electrical equipment. The system includes a processor performing any one of the preceding methods for risk assessment of the insulation state of the electrical equipment.

The system for risk assessment of an insulation state of electrical equipment further includes multiple sensors coupled to the processor.

The present application further provides a computer storage medium configured to store computer-executable instructions. The computer-executable instructions are used for performing any one of the preceding methods.

### BRIEF DESCRIPTION OF DRAWINGS

Various other advantages and benefits in the present application are apparent to those skilled in the art through reading the detailed description of the specific embodiments hereinafter. The drawings in the description are only used for the purpose of illustrating the embodiments and are not construed as a limit of the present invention. Apparently, the appended drawings described herein are merely part of embodiments of the present application, and those skilled in the art may obtain other drawings based on these appended drawings on the premise that no creative work is done. Moreover, the same reference numerals in the drawings indicate the same components.

FIG. 1 is a flowchart of a method for risk assessment of an insulation state of electrical equipment according to an embodiment of the present application.

FIG. 2 is a relative energy ternary diagram under three discharges according to a method for risk assessment of an insulation state of electrical equipment according to an embodiment of the present application.

FIG. 3 is a diagram illustrating the posterior probability of discharge type identification according to a method for risk assessment of an insulation state of electrical equipment according to an embodiment of the present application.

FIG. 4A is a diagram of the regression model of the partial discharge ternary energy mode and the apparent discharge energy according to a method for risk assessment of an insulation state of electrical equipment according to an embodiment of the present application, corresponding to corona discharge.

FIG. 4B is a diagram of the regression model of the partial discharge ternary energy mode and the apparent discharge energy according to a method for risk assessment of an insulation state of electrical equipment according to an embodiment of the present application, corresponding to creeping discharge.

FIG. 4C is a diagram of the regression model of the partial discharge ternary energy mode and the apparent discharge energy according to a method for risk assessment of an insulation state of electrical equipment according to an embodiment of the present application, corresponding to floating potential discharge.

FIG. 5A is a diagram illustrating the predicted value and actual value verification of apparent discharge energy and the relationship between cumulative discharge time and risk assessment level according to a method for risk assessment of an insulation state of electrical equipment according to an embodiment of the present application, corresponding to corona discharge.

FIG. 5B is a diagram illustrating the predicted value and actual value verification of apparent discharge energy and the relationship between cumulative discharge time and risk assessment level according to a method for risk assessment of an insulation state of electrical equipment according to an embodiment of the present application, corresponding to creeping discharge.

FIG. 5C is a diagram illustrating the predicted value and actual value verification of apparent discharge energy and the relationship between cumulative discharge time and risk assessment level according to a method for risk assessment of an insulation state of electrical equipment according to an embodiment of the present application, corresponding to floating potential discharge.

Hereinafter the present application is explained in conjunction with drawings and embodiments.

### DETAILED DESCRIPTION

Internal insulation defects in GIS may cause partial discharge under the action of an electric field. Partial discharge occurs in weak parts of the insulation of electrical equipment under the action of a strong electric field, which is a common situation in high-voltage electrical equipment. Although partial discharge generally does not cause penetrating breakdown of the insulation, local damage to dielectrics, especially organic dielectrics, may be caused. If partial discharge exists for a long time, insulation degradation or even breakdown may be caused under certain conditions. Conducting partial discharge tests on an electrical equipment may not only facilitate an understanding of the insulation state of the equipment but also detect many problems concerning manufacturing and installation in time and determine the cause and severity of the insulation faults.

In the process of instantaneous or sustained discharge, energy is released to molecules, ions, and electrons in space through discharge, exciting light, heat, sound, and other forms of energy. According to various physical processes existing in the partial discharge process, detection methods such as an ultra-high frequency detection method, an optical detection method, an ultrasonic detection method, and a pulse current method emerge accordingly. However, in the degradation process of the insulation medium, the partial discharge amplitude measured by the preceding methods does not continue to increase, and the partial discharge amplitude is lower at the stage when the insulation medium is close to penetration. Therefore, the degree of degradation of the insulation cannot be inferred from the amplitude alone, which causes great difficulty in assessing the insulation state of the electrical equipment.

To accurately measure the insulation state of electrical equipment and avoid misjudgment caused by a single detection amplitude, embodiments of the present application propose a method, an apparatus, and a system for risk assessment of an insulation state of electrical equipment and a storage medium.

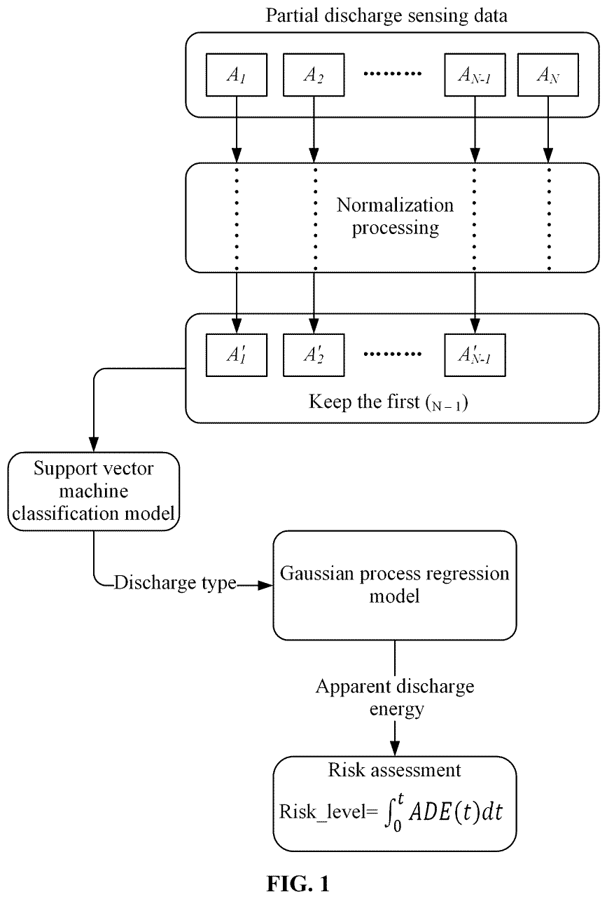

Embodiments of the present application are described in more detail below with reference to FIGS. 1 to 5C. The drawings illustrate the embodiments of the present application, but it should be understood that the present application may be implemented in various manners and should not be limited to the embodiments set forth herein. On the contrary, these embodiments are provided for a thorough understanding of the present application and to fully convey the scope of the present application to those skilled in the art.

For example, “comprising” or “including”, as referred to throughout the description and claims, is an open-ended term and is to be construed as “comprising, but not limited to”. The subsequent descriptions in the description are embodiments of the present application, but the descriptions are for the purpose of general principles of the description and are not intended to limit the scope of the present application. The scope of the present application shall be as defined in the appended claims.

To facilitate an understanding of the embodiments of the present application, an explanation is given below with reference to the accompanying drawings using embodiments as examples, and each drawing does not constitute a limitation to the embodiments of the present application.

For a better understanding, FIG. 1 shows a method for risk assessment of an insulation state of electrical equipment. As shown in FIG. 1, the method for risk assessment of an insulation state of electrical equipment includes the steps below.

In step 1, partial discharge data of electrical equipment are measured using multiple types of sensors, and clustering of discharge types is performed.

In step 2, based on the clustering result of each discharge type, a regression model between sensor response amplitude and apparent discharge energy is established during a discharge development process.

In step 3, based on the regression model, the accumulated value of apparent discharge energy of current partial discharge of the electrical equipment is calculated, and the accumulated value is used as an index of risk assessment to assess an insulation state of the electrical equipment.

In step 1 in an embodiment of the method, in the case where a high-frequency current sensor is not used, a total of N sensors of different types are used to collect the partial discharge data of the electrical equipment, and the response amplitude Aᵢ of each sensor is normalized to obtain Aᵢ:

$${A}_{i}^{′} = \frac{{A}_{i}}{{\sum }_{k = 1}^{N} {A}_{k}} .$$

Aᵢ denotes response amplitude of a sensor numbered i under the action of partial discharge pulse, and Σₖ₌₁^{N} Aₖ denotes the sum of response amplitudes of the N sensors.
The normalized result {A′₁, A′₂, . . . , A′_{N-1}} of the response amplitude of previous (N−1) sensors is used as input, and support vector machine (SVM) clustering is performed on the discharge types to establish a clustering area in (N−1) dimensional space.

In step 2 in an embodiment of the method, Gaussian process regression is used to describe the relationship between (N−1) dimensional space constituted by {A′₁, A′₂, . . . , A′_{N-1}} and the apparent discharge energy (ADE); the apparent discharge energy is measured by a high-frequency current sensor, and the Gaussian process ƒ(x) is described by a mean function m(x) and a covariance function k(x, x′) as follows: ƒ(x)˜GP(m(x), k(x, x′)).

The covariance function k(x, x′) is of a square exponential type, that is,

$$k ( x , {x}^{′} ) = exp ( - \frac{\sqrt{{( x - {x}^{′} )}^{T} ( x - {x}^{′} )}}{2} ) .$$

In an embodiment, the parameter of the regression model based on the Gaussian process regression is determined by a training data set, and the training data set is: X=(x₁, x₂, . . . , xₙ), Y=(y₁, y₂, . . . , yₙ)^{T}.

In the covariance function k(x, x′), when x takes xᵢ, xᵢ denotes a vector composed of response amplitude of a sensor under an action of an i-th discharge pulse: xᵢ=(A′₁, A′₂, . . . , A′_{N-1})^{T}. i ranges from 1 to n, and n is an n-th discharge pulse.

When x takes xᵢ, x′ takes xⱼ, xⱼ denotes a vector of a same type as xᵢ, j ranges from 1 to n, and j is not equal to i.

x and x′ are independent variables corresponding to vectors composed of the response amplitudes of sensors under an action of different discharge pulses, x and x′ are not equal in form.

When i ranges from 1 to n, yᵢ denotes apparent discharge energy measured by a high-frequency current sensor under the action of the i-th discharge pulse;

In an embodiment, a random vector of prediction variable distribution of the training data set is generated as follows:

$$Y = f ( X ) + ε ∼ N ( μ ( X ) , K ( X , X ) + {σ}^{2} {I}_{n} ) .$$

The joint distribution of the function value Y and the observation target value f* is expressed as follows:

$$[ \begin{matrix}Y \\ {f}_{*}\end{matrix} ] ∼ N ( [ \begin{matrix}μ ( X ) \\ μ ( {X}_{*} )\end{matrix} ] , \begin{matrix}K ( X , X ) + {σ}^{2} {I}_{n} & K ( X , {X}_{*} ) \\ K ( {X}_{*} , X ) & K ( {X}_{*} , {X}_{*} )\end{matrix} ) .$$

The observation target value f* is a predicted value of the discharge energy to be predicted, and the predicted value of the discharge energy is an output of the regression model.

Iₙ denotes an n-order identity matrix whose diagonal elements are 1 and remaining elements are 0, and X_{*}=(x₁, x₂, . . . , xₙ, xₙ₊₁) is composed of all elements in the training data set X=(x₁, x₂, . . . , xₙ) and new observation data xₙ₊₁.

μ(X) is a mean vector of the training data set X, and an i-th component of μ(X) is an average of all elements in an i-th row of X.

μ(X_{*}) is a mean vector of X_{*}, and an i-th component of μ(X_{*}) is an average of all elements in an i-th row of X_{*}.

ε is Gaussian noise, and the Gaussian noise E obeys a normal distribution N(μ(X), K(X,X)+σ²Iₙ).

σ is a random error contained in a variance of the normal distribution N(μ(X), K(X,X)+σ²Iₙ), and the random error reduces an impact of a measurement error present in the training data set;

K(X,X) is a covariance matrix, and an element in an i-th row and a j-th column of the covariance matrix is obtained by taking a squared exponential kernel function of an i-th column element xᵢ of X and a j-th column element xⱼ of X:

$$k ( {x}_{i} , {x}_{j} ) = exp ( - \frac{\sqrt{{( {x}_{i} - {x}_{j} )}^{T} ( {x}_{i} - {x}_{j} )}}{2} ) .$$

An element in an i-th row and a j-th column of a covariance matrix K(X,X_{*}) is obtained by taking a squared exponential kernel function of an i-th column element xᵢ of X and a j-th column element xⱼ of X_{*}.

An element in an i-th row and a j-th column of K(X_{*}, X) is obtained by taking a squared exponential kernel function of an i-th column element xᵢ of X_{*} and a j-th column element x₁ of X.

An element in an i-th row and a j-th column of K(X_{*},X_{*}) is obtained by taking a squared exponential kernel function of an i-th column element xᵢ of X_{*} and a j-th column element xⱼ of X_{*}.

In the case where Y, X, X_{*} are known, conditional distribution of ƒ_{*} is normal distribution of mean μ_{*} and variance Σ_{*}:

P(ƒ_{*}|Y,X,X_{*})˜N(μ_{*},Σ_{*}).

The mean μ_{*} and variance Σ_{*} are as follows:

$${μ}_{*} = K ( {X}_{*} , X ) {( K ( X , X ) + {σ}^{2} {I}_{n} )}^{- 1} ( Y - μ ( X ) ) + μ ( {X}_{*} ) , {\sum }_{*} = K ( {X}_{*} , {X}_{*} ) - K ( {X}_{*} , X ) {( K ( X , X ) + {σ}^{2} {I}_{n} )}^{- 1} K ( X , {X}_{*} ) .$$

Thus, the mean and variance corresponding to the new observation data xₙ₊₁ may be obtained from the conditional distribution of ƒ_{*}, and thus the predicted value of the apparent discharge energy is obtained.

In an embodiment, for each sensor, when the corresponding sensor response amplitude is known during the discharge development process, and when the corresponding predicted value of apparent discharge energy is obtained, a regression model is established between the response amplitude of each sensor and the apparent discharge energy during the discharge development process according to the regression model.

In step 3 in an embodiment of the method, the predicted value of apparent discharge energy corresponding to the current discharge pulse point of the electrical equipment in the regression model is found.

ADE(t)=ƒ(A₁′(t),A₂′(t), . . . ,A_{N-1}(t))

A′ᵢ(t) denotes a normalized result of response amplitude of an i-th sensor under a discharge pulse signal at time t, and ADE(t) denotes the predicted value of the apparent discharge energy obtained from the discharge pulse signal at the time t.

Predicted values of the apparent discharge energy and time are accumulated during a monitoring and early warning process to determine the insulation risk level:

$$Risk\_leνel = {\int }_{0}^{t} A D E ( t ) dt .$$

∫₀^{t} ADE(t)dt denotes the integral of the apparent discharge energy from 0 to t.

When Risk_level<α, it is determined that the detected electrical equipment has no discharge.

When α≤Risk_level≤β, it is determined that a slight partial discharge occurs in the detected electrical equipment.

When Risk_level>β, it is determined that a serious discharge occurs in the detected electrical equipment. The threshold α is set according to 120% of the risk index under background noise of an operation site of the electrical equipment. The threshold β is set according to the risk index at the maximum temperature allowed under a rated operation state of the electrical equipment.

In an embodiment, the discharge type includes corona discharge, creeping discharge, and floating potential discharge.

In an embodiment, the multiple types of sensors include an optical sensor, an ultra-high frequency sensor, and an ultrasonic sensor.

In an embodiment, the preceding method of performing Gaussian process regression on the apparent discharge energy (ADE) using normalized sensing parameters may be implemented by calling the “fitrgp” toolbox of matlab or by using the following code:

num = length(gc_x);
K = zeros(num,num);
Ks = zeros(num,length(x));
Kss = zeros(length(x),length(x));
for i=1:num
for j=1:num
a. K(i,j) =exp(−((gc_x(i)−gc_x(j)).\hat{ }2));
end
for j=1:length(x)
b. Ks(i,j) = exp(−((gc_x(i)−x(j)).\hat{ }2));
end
end
for i=1:length(x)
for j=1:length(x)
c. Kss(i,j) = exp(−((x(i)−x(j)).\hat{ }2));
end
end
sigma = 0.001;
std_y = diag(Kss − Ks′*inv(K + sigma*eye(length(K)))*Ks);
mean_y = Ks′*inv(K + sigma*eye(length(K)))*gc_y′.

In the preceding code, the variable gc_x denotes a matrix composed of normalized sensing parameters {A′₁, A′₂, . . . , A′_{N-1}}, the variable gc_y denotes an array composed of apparent discharge energy measured by the high-frequency Rogowski coils, the variable x denotes data to be predicted, and mean_y denotes a predicted value of the apparent discharge energy.

In an embodiment, a partial discharge signal is collected using a pulse current sensor (high-frequency Rogowski coils) of a pulse current method, an optical sensor of an optical detection method, an ultra-high frequency sensor of an ultra-high frequency method, and an ultrasonic sensor of an ultrasonic method. Discharge types include corona discharge, creeping discharge, and floating potential discharge.

In an embodiment, the data obtained by the optical detection method, ultra-high frequency method, and ultrasonic method are normalized:

$${A}_{A E}^{′} = \frac{{A}_{A E}}{{A}_{A E} + {A}_{L i g h t} + {A}_{U H F}} , {A}_{L i g h t}^{′} = \frac{{A}_{L i g h t}}{{A}_{A E} + {A}_{Light} + {A}_{U H F}} , {A}_{U H F}^{′} = \frac{{A}_{U H F}}{{A}_{AE} + {A}_{L i g h t} + {A}_{U H F}} .$$

A_{AE} denotes the amplitude measured by the ultrasonic sensor, A_{light} denotes the amplitude measured by the optical sensor, A_{UHF} denotes the amplitude measured by the ultra-high frequency sensor, and correspondingly A′ denotes the corresponding normalized result.

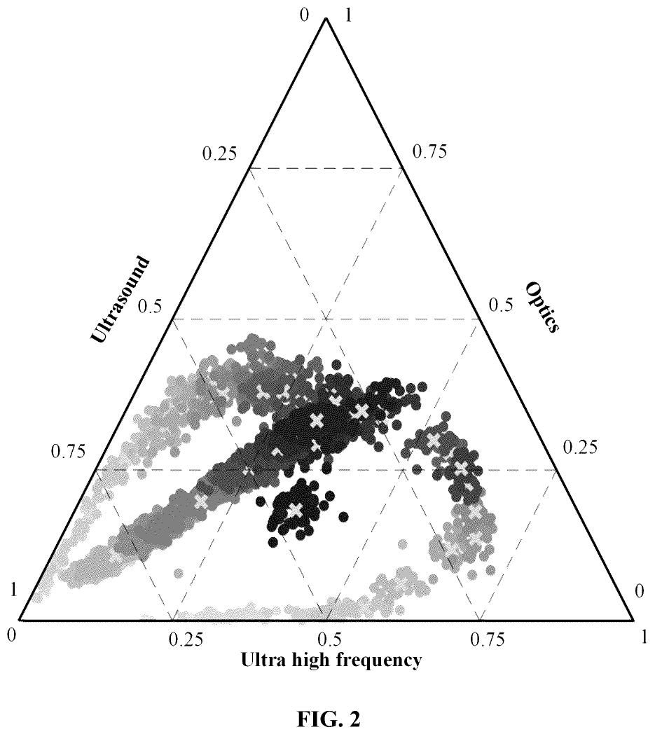

The result is plotted in David's triangle to obtain a relative energy ternary diagram under three discharges, as shown in FIG. 2. In FIG. 2, the coordinate calculation formula of each point is as follows:

$$\{ \begin{matrix}x = {A}_{A E}^{′} + \frac{1}{2} {A}_{Light}^{′} \\ y = \frac{\sqrt{3}}{2} {A}_{L i g h t}^{′}\end{matrix} .$$

The coordinates of the data points in FIG. 2 are used as data set variables, and discharge types, including creeping discharge, corona discharge, and floating potential discharge, are used as label data; support vector machine is used to cluster discharge types. To obtain the confidence probability of the clustering result, an output transformation is performed using the following method:

$$P ( y = 1 \vert x ) = \frac{1}{1 + exp ( Af ( x ) + B )} .$$

In an example, the values of parameters A and B in the preceding equation are obtained by solving the following regularized maximum likelihood function:

$$min F ( A , B ) = - {\sum }_{i = 1}^{m} [ {t}_{i} log ( {p}_{i} ) + ( 1 - {t}_{i} ) log ( 1 - {p}_{i} ) ] .$$

In the preceding formula,

$${p}_{i} \frac{1}{1 + exp ( Af ( {x}_{i} ) + B )} ,$$

and m is the number of data samples.

$${t}_{i} = \{ \begin{matrix}\frac{{N}_{+} + 1}{{N}_{+} + 2} , & {y}_{i} = 1 \\ \frac{1}{{N}_{-} + 2} , & {y}_{i} = - 1\end{matrix} .$$

yᵢ is the classification label of the i-th sample; N₊ and N₋ are the number of positive samples and the number of negative samples, respectively.

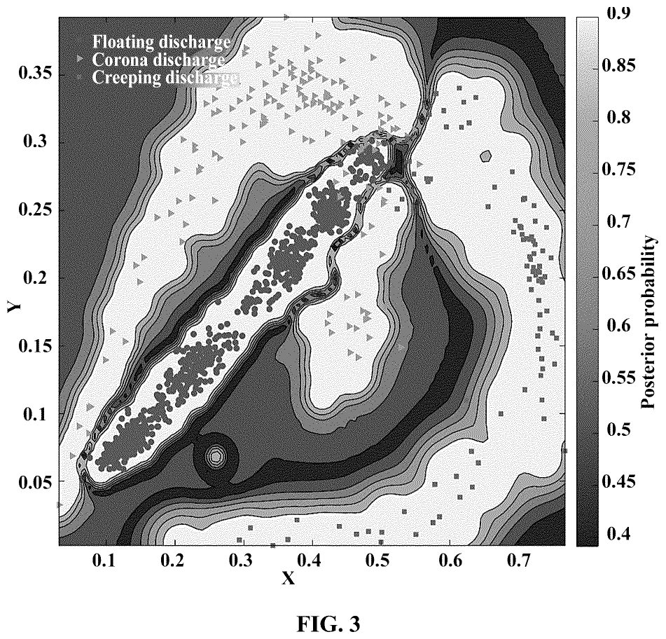

The resulting posterior probability is shown in FIG. 3.

For each type of discharge, the coordinates of the data points in the ternary diagram are used as the data set variables, and the apparent discharge energy measured by the high-frequency Rogowski coils is used as the prediction variable. Gaussian process regression is used to establish a regression model between the partial discharge ternary energy mode and the apparent discharge energy:

$$A D E = f ( x ) ∼ GP ( m ( x ) , k ( x , {x}^{′} ) ) .$$

The covariance matrix is calculated using the Gaussian kernel function:

$$k ( {x}_{i} , {x}_{j} ) = {σ}_{f}^{2} exp ( - \frac{\sqrt{{( {x}_{i} - {x}_{j} )}^{T} ( {x}_{i} - {x}_{j} )}}{2 {σ}_{i}^{2}} ) .$$

The apparent discharge energy (ADE) obeys an n-element Gaussian joint distribution on the data set, and for a new data point, ADE obeys an (n+1)-element Gaussian joint distribution:

$$[ \begin{matrix}Y \\ {f}_{*}\end{matrix} ] ∼ N ( [ \begin{matrix}μ ( X ) \\ μ ( {X}_{*} )\end{matrix} ] , \begin{matrix}K ( X , X ) + {σ}^{2} {I}_{n} & K ( X , {X}_{*} ) \\ K ( {X}_{*} , X ) & K ( {X}_{*} , {X}_{*} )\end{matrix} ) .$$

Then at the new data point, the conditional distribution is a unary Gaussian distribution: P(ƒ_{*}|Y,X,X_{*})˜N(μ_{*}, Σ_{*}).

The calculation formulas of mean and variance are as follows:

$${μ}_{*} = K ( {X}_{*} , X ) {( K ( X , X ) + {σ}^{2} {I}_{n} )}^{- 1} ( Y - μ ( X ) ) + μ ( {X}_{*} ) , {\sum }_{*} = K ( {X}_{*} , {X}_{*} ) - K ( {X}_{*} , X ) {( K ( X , X ) + {σ}^{2} {I}_{n} )}^{- 1} K ( X , {X}_{*} ) .$$

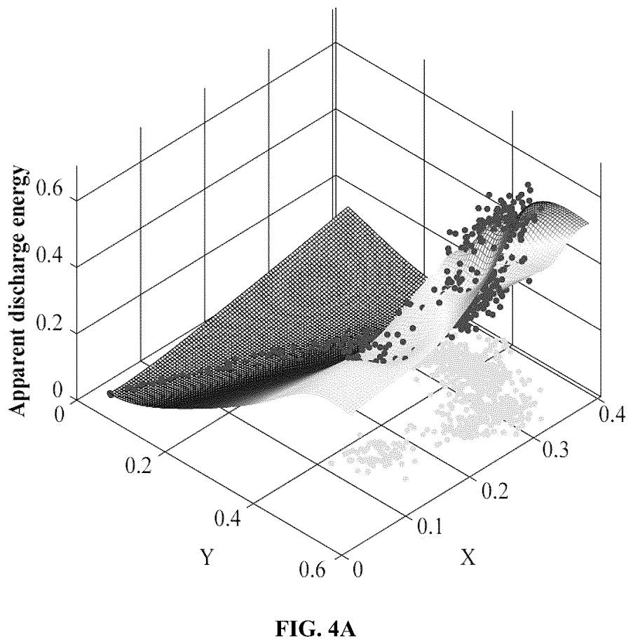

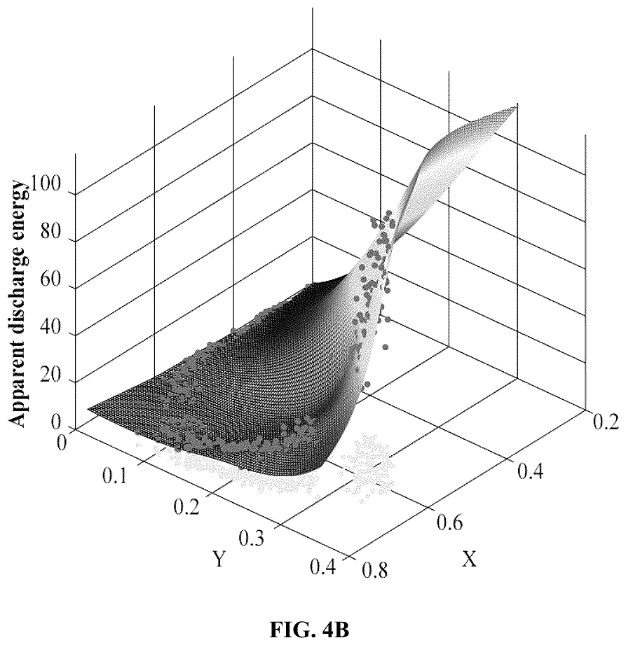

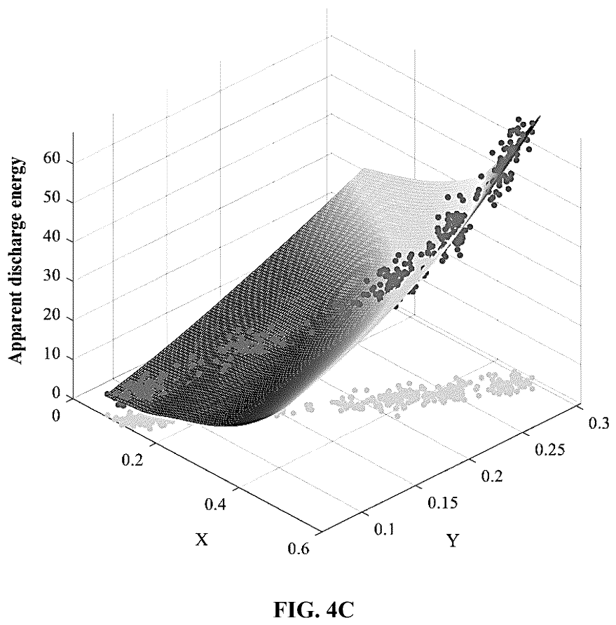

Thus, the mean and variance of the Gaussian distribution of ADE at any point can be obtained, and the variance may provide a confidence interval, and the mean may be used as the predicted value of ADE. The predicted value of the apparent discharge energy is used as the z-axis, and the regression surface is plotted in a 3-dimensional coordinate system, as shown in FIGS. 4A to 4C. FIGS. 4A, 4B, and 4C are results under corona discharge, creeping discharge, and floating discharge, respectively. It can be seen from FIGS. 4A to 4C that under three different types of discharge, the discharge data points all fall on the fitting surface obtained by Gaussian process regression, which proves the effectiveness of the Gaussian process regression model in this embodiment.

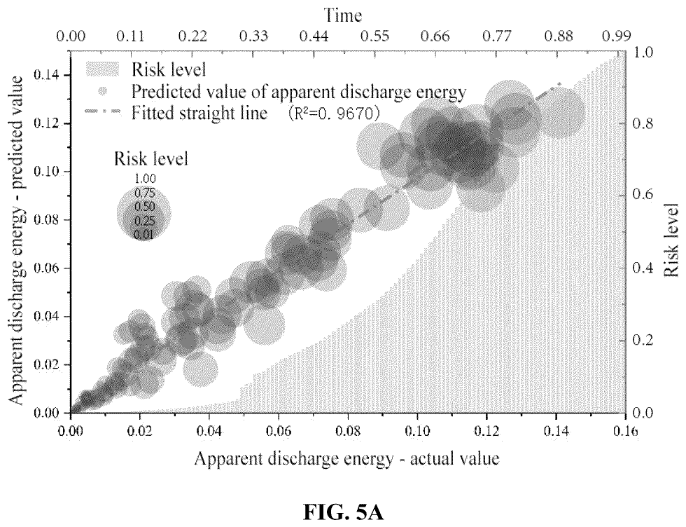

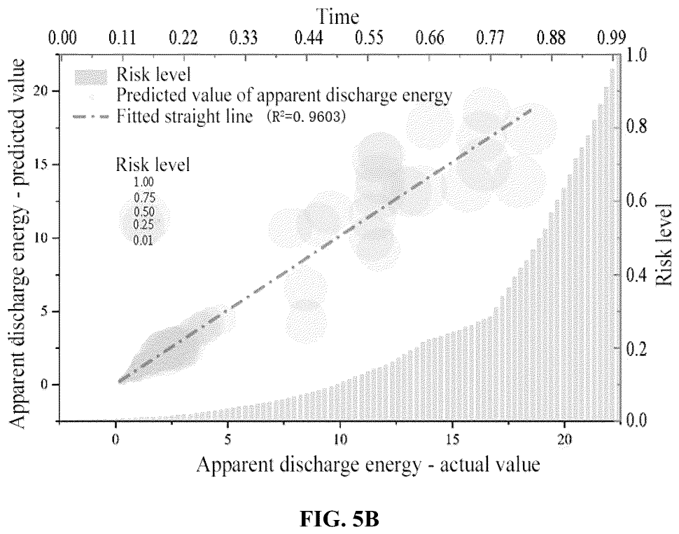

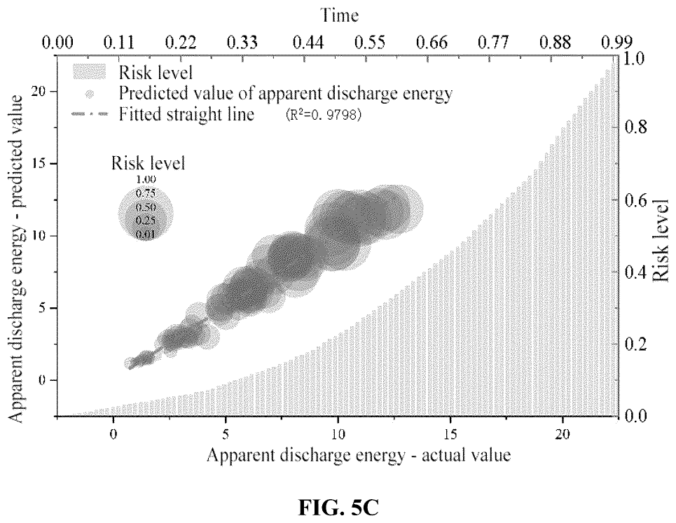

To measure the effect of the method for risk assessment described in the present application, diagrams of the predicted value and actual value verification of apparent discharge energy and of the relationship between cumulative discharge time and risk assessment level are plotted, as shown in FIGS. 5A to 5C. FIGS. 5A, 5B, and 5C are results under corona discharge, creeping discharge, and floating discharge, respectively. As can be seen from FIGS. 5A to 5C, a pulse mode with weaker ADE may have a relatively high-risk index, indicating that it is difficult to perform risk assessment solely by the size of the ADE; the quadratic coordinates (upper and right coordinate axes) represent the correlation between the risk level and the risk index by a histogram, which shows that basically a positive correlation exists between the two assessment indexes, which proves the effectiveness of the method for risk assessment proposed by the present application.

The method for risk assessment of an insulation state of electrical equipment according to embodiments of the present application accurately and reliably measures the insulation state of the electrical equipment.

Embodiments of the present application propose a method of using multi-parameter data to identify discharge types of different scales and a dynamic assessment method of insulation state based on the energy accumulation process of discharge development, which can accurately characterize the severity of partial discharge and provide a reliable solution for the insulation state early warning of the online monitoring system.

In an embodiment, the present application further provides a system for risk assessment of an insulation state of electrical equipment. The system includes a processor performing any one of the preceding methods for risk assessment of the insulation state of the electrical equipment.

The system for risk assessment of an insulation state of electrical equipment further includes multiple sensors coupled to the processor.

In an embodiment, the sensor includes a partial discharge sensor.

In an embodiment, the processor includes a single-chip microcomputer.

In an embodiment, the processor includes a wireless communication unit.

The present application further provides an apparatus for risk assessment of an insulation state of electrical equipment. The apparatus includes a clustering unit, a modeling unit, and an assessment unit.

The clustering unit is configured to measure partial discharge data of electrical equipment using multiple types of sensors and perform clustering of discharge types.

The modeling unit is configured to establish, based on a clustering result of each discharge type, a regression model between sensor response amplitude and apparent discharge energy during a discharge development process.

The assessment unit is configured to calculate, based on the regression model, the accumulated value of apparent discharge energy of current partial discharge of the electrical equipment and use the accumulated value as an index of risk assessment to assess an insulation state of the electrical equipment.

The present application further provides a computer storage medium configured to store computer-executable instructions. The computer-executable instructions are used for performing any one of the preceding methods.

It should be noted that in addition to the measurement of apparent discharge energy during the establishment of the regression model using a high-frequency current sensor, the types of sensors in the present application also include an optical sensor, an ultra-high frequency sensor, and an ultrasonic sensor. Although embodiments of the present application are described above in conjunction with drawings, the present application is not limited to the preceding embodiments and the fields of application. The preceding embodiments are merely illustrative and instructive rather than restrictive. Those of ordinary skill in the art, inspired by this description and without departing from the scope of the claims of the present application, may also make many forms, all of which fall within the scope of the present application.

1. A method for risk assessment of an insulation state of electrical equipment, comprising:
measuring partial discharge data of electrical equipment using a plurality of types of sensors, and performing clustering of discharge types;
establishing, based on a clustering result of each discharge type, a regression model between sensor response amplitude and apparent discharge energy during a discharge development process; and
calculating, based on the regression model, an accumulated value of apparent discharge energy of current partial discharge of the electrical equipment, wherein the accumulated value is used as an index of risk assessment to assess an insulation state of the electrical equipment.

2. The method of claim 1, wherein measuring the partial discharge data of the electrical equipment using the plurality of types of sensors and performing clustering of the discharge types comprises:
in a case where a high-frequency current sensor is not used, using a total of N sensors of different types to collect the partial discharge data of the electrical equipment, and normalizing response amplitude Aᵢ of each sensor to obtain A′ᵢ:
$${A}_{i}^{′} = \frac{{A}_{i}}{{\sum }_{k = 1}^{N} {A}_{k}} ,$$
wherein Aᵢ denotes response amplitude of a sensor numbered i under an action of partial discharge pulse, and Σₖ₌₁^{N}Aₖ denotes a sum of response amplitudes of the N sensors; and
using a normalized result {A′₁, A′₂, . . . , A′_{N-1}} of response amplitude of previous (N−1) sensors as input, and performing support vector machine (SVM) clustering on the discharge types to establish a clustering area in (N−1) dimensional space.

3. The method of claim 2, wherein establishing the regression model between the sensor response amplitude and the apparent discharge energy during the discharge development process based on the clustering result of the each discharge type comprises:
describing a relationship between (N−1) dimensional space constituted by {A′₁, A′₂, . . . , A′_{N-1}} and the apparent discharge energy using Gaussian process regression, wherein the Gaussian process ƒ(x) is described by a mean function m(x) and a covariance function k(x, x′) as:
ƒ(x)˜GP(m(x),k(x,x′)),
wherein the covariance function k(x, x′) is of a square exponential type:
$$k ( x , {x}^{′} ) = exp ( - \frac{\sqrt{{( x - {x}^{′} )}^{T} ( x - {x}^{′} )}}{2} ) ;$$
establishing the regression model based on the Gaussian process regression, wherein a parameter of the regression model is determined by a training data set, and the training data set is:
X=(x₁,x₂, . . . ,xₙ),Y=(y₁,y₂, . . . ,yₙ)^{T},
wherein
in the covariance function k(x, x′), when x takes xᵢ, xᵢ denotes a vector composed of response amplitude of a sensor under an action of an i-th discharge pulse: xᵢ=(A′₁, A′₂, . . . , A′_{N-1})^{T}, wherein i ranges from 1 to n, and n is an n-th discharge pulse;
when x takes xᵢ, x′ takes xⱼ, xⱼ denotes a vector of a same type as xᵢ, j ranges from 1 to n, and j is not equal to i;
x and x′ are independent variables corresponding to vectors composed of response amplitudes of sensors under an action of different discharge pulses, x and x′ are not equal in form;
when i ranges from 1 to n, yᵢ denotes apparent discharge energy measured by a high-frequency current sensor under the action of the i-th discharge pulse;
a random vector of prediction variable distribution of the training data set is generated as:
$$Y = f ( X ) + ε ∼ N ( μ ( X ) , K ( X , X ) + {σ}^{2} {I}_{n} ) ,$$
wherein joint distribution of a function value Y and an observation target value f* is expressed as:
$$[ \begin{matrix}Y \\ {f}_{*}\end{matrix} ] ∼ N ( [ \begin{matrix}μ ( X ) \\ μ ( {X}_{*} )\end{matrix} ] , \begin{matrix}K ( X , X ) + {σ}^{2} {I}_{n} & K ( X , {X}_{*} ) \\ K ( {X}_{*} , X ) & K ( {X}_{*} , {X}_{*} )\end{matrix} ) ,$$
wherein the observation target value f* is a predicted value of discharge energy to be predicted, and the predicted value of the discharge energy is an output of the regression model;
Iₙ denotes an n-order identity matrix whose diagonal elements are 1 and remaining elements are 0, and X_{*}=(x₁, x₂, . . . , xₙ, xₙ₊₁) is composed of all elements in the training data set X=(x₁, x₂, . . . , xₙ) and new observation data xₙ₊₁,
μ(X) is a mean vector of the training data set X, and an i-th component of μ(X) is an average of all elements in an i-th row of X;
μ(X_{*}) is a mean vector of X_{*}, and an i-th component of μ(X_{*}) is an average of all elements in an i-th row of X_{*};
ε is Gaussian noise, and the Gaussian noise ε obeys a normal distribution N(μ(X),K(X,X)+σ²Iₙ);
σ is a random error contained in a variance of the normal distribution N(μ(X),K(X,X)+σ²Iₙ), and the random error reduces an impact of a measurement error present in the training data set;
K(X,X) is a covariance matrix, and an element in an i-th row and a j-th column of the covariance matrix is obtained by taking a squared exponential kernel function of an i-th column element xᵢ of X and a j-th column element xⱼ of X:
$$k ( {x}_{i} , {x}_{j} ) = exp ( - \frac{\sqrt{{( {x}_{i} - {x}_{j} )}^{T} ( {x}_{i} - {x}_{j} )}}{2} ) ;$$
an element in an i-th row and a j-th column of a covariance matrix K(X,X_{*}) is obtained by taking a squared exponential kernel function of an i-th column element xᵢ of x and a j-th column element xⱼ of X_{*};
an element in an i-th row and a j-th column of K(X_{*},X) is obtained by taking a squared exponential kernel function of an i-th column element xᵢ of X_{*} and a j-th column element xⱼ of X;
an element in an i-th row and a j-th column of K(X_{*},X_{*}) is obtained by taking a squared exponential kernel function of an i-th column element xᵢ of X_{*} and a j-th column element xⱼ of X_{*};
in a case where Y,X,X_{*} are known, conditional distribution of ƒ_{*} is normal distribution of mean μ_{*} and variance Σ_{*}:
P(ƒₛ|Y,X,X_{*})˜N(μ_{*},Σ_{*})
wherein the mean μ_{*} and variance Σ_{*} are:
$${μ}_{*} = K ( {X}_{*} , X ) {( K ( X , X ) + {σ}^{2} {I}_{n} )}^{- 1} ( Y - μ ( X ) ) + μ ( {X}_{*} ) \\ {\sum }_{*} = K ( {X}_{*} , {X}_{*} ) - K ( {X}_{*} , X ) {( K ( X , X ) + {σ}^{2} {I}_{n} )}^{- 1} K ( X , {X}_{*} ) ;$$
and
obtaining mean and variance corresponding to the new observation data xₙ₊₁ from the conditional distribution of ƒ_{*}, to obtain a predicted value of the apparent discharge energy, that is, the observation target value ƒ_{*}.

4. The method of claim 1, wherein calculating the accumulated value of the apparent discharge energy of the current partial discharge of the electrical equipment based on the regression model and using the accumulated value as the index of risk assessment to assess the insulation state of the electrical equipment comprise:
finding a predicted value of apparent discharge energy corresponding to a current discharge pulse point of the electrical equipment in the regression model:
ADE(t)=ƒ(A₁′(t),A₂′(t), . . . ,A_{N-1}′(t)),
wherein A′ᵢ(t) denotes a normalized result of response amplitude of an i-th sensor under a discharge pulse signal at time t, and ADE(t) denotes a predicted value of the apparent discharge energy obtained from the discharge pulse signal at the time t; and
accumulating predicted values of the apparent discharge energy and time during a monitoring and early warning process to determine an insulation risk level:
$$Risk\_level = {\int }_{0}^{t} ADE ( t ) dt ,$$
wherein ∫₀^{t} ADE(t)dt denotes integral of the apparent discharge energy from 0 to t;
in a case where Risk_level<α, determining that the electrical equipment has no discharge;
in a case where α≤Risk_level≤β, determining that a slight partial discharge occurs in the electrical equipment; and
in a case where Risk_level>β, determining that a serious discharge occurs in the electrical equipment; wherein a threshold α is set according to 120% of risk index under background noise of an operation site of the electrical equipment; and a threshold β is set according to a risk index at maximum temperature allowed under a rated operation state of the electrical equipment.

5. The method of claim 1, wherein the discharge types comprise corona discharge, creeping discharge, and floating potential discharge.

6. The method of claim 1, wherein the plurality of types of sensors comprise an optical sensor, an ultra-high frequency sensor, and an ultrasonic sensor.

7. (canceled)

8. A system for risk assessment of an insulation state of electrical equipment, comprising a memory and a processor, wherein the memory stores a computer program which, when executed by the processor, causes the processor to perform:
measuring partial discharge data of electrical equipment using a plurality of types of sensors, and performing clustering of discharge types;
establishing, based on a clustering result of each discharge type, a regression model between sensor response amplitude and apparent discharge energy during a discharge development process; and
calculating, based on the regression model, an accumulated value of apparent discharge energy of current partial discharge of the electrical equipment, wherein the accumulated value is used as an index of risk assessment to assess an insulation state of the electrical equipment.

9. The system of claim 8, further comprising a plurality of sensors coupled to the processor.

10. A non-transitory computer storage medium configured to store computer-executable instructions, wherein the computer-executable instructions, when executed by a processor, causes the processor to perform:
measuring partial discharge data of electrical equipment using a plurality of types of sensors, and performing clustering of discharge types;
establishing, based on a clustering result of each discharge type, a regression model between sensor response amplitude and apparent discharge energy during a discharge development process; and
calculating, based on the regression model, an accumulated value of apparent discharge energy of current partial discharge of the electrical equipment, wherein the accumulated value is used as an index of risk assessment to assess an insulation state of the electrical equipment.

11. The system of claim 8, wherein the processor is caused to measure the partial discharge data of the electrical equipment using the plurality of types of sensors and performing clustering of the discharge types in the following manners:
in a case where a high-frequency, current sensor is not used, using a total of N sensors of different types to collect the partial discharge data of the electrical equipment, and normalizing response amplitude Aᵢ of each sensor to obtain A′ᵢ:
$${A}_{i}^{′} = \frac{{A}_{i}}{{\sum }_{k = 1}^{N} {A}_{k}} ,$$
wherein Aᵢ denotes response amplitude of a sensor numbered i under an action of partial discharge pulse, and Σₖ₌₁^{N} Aₖ denotes a sum of response amplitudes of the N sensors, and
using a normalized result {A′₁, A′₂, . . . , A′_{N-1}} of response amplitude of previous (N−1) sensors as input, and performing support vector machine (SVM) clustering on the discharge types to establish a clustering area in (N−1) dimensional space.

12. The system of claim 11, wherein the processor is caused to establish the regression model between the sensor response amplitude and the apparent discharge energy during the discharge development process based on the clustering result of the each discharge type in the following manners:
describing a relationship between (N−1) dimensional space constituted by {A′₁, A′₂, . . . , A′_{N-1}} and the apparent discharge energy using Gaussian process regression, wherein the Gaussian process ƒ(x) is described by a mean function m(x) and a covariance function k(x, x′) as:
ƒ(x)˜GP(m(x),k(x,x′)),
wherein the covariance function k(x, x′) is of a square exponential type:
$$k ( x , {x}^{′} ) = exp ( - \frac{\sqrt{{( x − {x}^{′} )}^{T} ( x − {x}^{′} )}}{2} ) ;$$
establishing the regression model based on the Gaussian process regression, wherein a parameter of the regression model is determined by a training data set, and the training data set is:
X=(x₁,x₂, . . . ,xₙ),Y=(y₁,y₂, . . . ,yₙ)^{T},
wherein
in the covariance function k(x, x′), when x takes xᵢ, xᵢ denotes a vector composed of response amplitude of a sensor under an action of an i-th discharge pulse: xᵢ=(A′₁, A′₂, . . . , A′_{N-1})^{T}, wherein i ranges from 1 to n, and n is an n-th discharge pulse;
when x takes xᵢ, x′ takes xⱼ, xⱼ denotes a vector of a same type as xᵢ, j ranges from 1 to n, and j is not equal to i;
x and x′ are independent variables corresponding to vectors composed of response amplitudes of sensors under an action of different discharge pulses, x and x′ are not equal in form;
when i ranges from 1 to n, yᵢ denotes apparent discharge energy measured by a high-frequency current sensor under the action of the i-th discharge pulse;
a random vector of prediction variable distribution of the training data set is generated as:
$$Y = f ( X ) + ε ∼ N ( μ ( X ) , K ( X , X ) + {σ}^{-} {I}_{n} ) ,$$
wherein joint distribution of a function value Y and an observation target value f* is expressed as:
$$[ \begin{matrix}Y \\ {f}_{*}\end{matrix} ] ∼ N ( [ \begin{matrix}μ ( X ) \\ μ ( {X}_{*} )\end{matrix} ] , \begin{matrix}K ( X , X ) + {σ}^{2} {I}_{n} & K ( X , {X}_{*} ) \\ K ( {X}_{*} , X ) & K ( {X}_{*} , {X}_{*} )\end{matrix} ) ,$$
wherein the observation target value f* is a predicted value of discharge energy to be predicted, and the predicted value of the discharge energy is an output of the regression model;
Iₙ denotes an n-order identity matrix whose diagonal elements are 1 and remaining elements are 0, and X_{*}=(x₁, x₂, . . . , xₙ, xₙ₊₁) is composed of all elements in the training data set X=(x₁, x₂, . . . , xₙ) and new observation data xₙ₊₁,
μ(X) is a mean vector of the training data set X, and an i-th component of μ(X) is an average of all elements in an i-th row of X;
μ(X_{*}) is a mean vector of X_{*}, and an i-th component of μ(X_{*}) is an average of all elements in an i-th row of X_{*};
ε is Gaussian noise, and the Gaussian noise ε obeys a normal distribution N(μ(X),K(X,X)+σ²Iₙ);
σ is a random error contained in a variance of the normal distribution N(μ(X),K(X,X)+σ²Iₙ), and the random error reduces an impact of a measurement error present in the training data set;
K(X,X) is a covariance matrix, and an element in an i-th row and a j-th column of the covariance matrix is obtained by taking a squared exponential kernel function of an i-th column element xᵢ of X and a j-th column element xⱼ of X:
$$k ( {x}_{i} , {x}_{j} ) = exp ( - \frac{\sqrt{{( {x}_{\dot{i}} - {x}_{j} )}^{T} ( {x}_{i} - {x}_{j} )}}{2} ) ;$$
an element in an i-th row and a j-th column of a covariance matrix K(X,X_{*}) is obtained by taking a squared exponential kernel function of an i-th column element xᵢ of X and a j-th column element xⱼ of X_{*};
an element in an i-th row and a j-th column of K(X_{*},X) is obtained by taking a squared exponential kernel function of an i-th column element xᵢ of X_{*} and a j-th column element xⱼ of X;
an element in an i-th row and a j-th column of K(X_{*},X_{*}) is obtained by taking a squared exponential kernel function of an i-th column element xᵢ of X_{*} and a j-th column element xⱼ of X_{*};
in a case where Y,X,X_{*} are known, conditional distribution of ƒ_{*} is normal distribution of mean μ_{*} and variance Σ_{*}:
P(ƒₛ|Y,X,X_{*})˜N(μ_{*},Σ_{*})
wherein the mean μ_{*} and variance Σ_{*} are:
$${μ}_{⋆} = K ( {X}_{⋆} , X ) {( K ( X , X ) + {σ}^{2} {I}_{n} )}^{− 1} ( Y - μ ( X ) ) + μ ( {X}_{⋆} )$$
$${\sum }_{⋆} = K ( {X}_{⋆} , {X}_{⋆} ) − K ( {X}_{⋆} , X ) {( K ( X , X ) + {σ}^{2} {I}_{n} )}^{− 1} K ( X , {X}_{⋆} ) ;$$
and
obtaining mean and variance corresponding to the new observation data xₙ₊₁ from the conditional distribution of ƒ_{*}, to obtain a predicted value of the apparent discharge energy, that is, the observation target value ƒ_{*}.

13. The system of claim 8, wherein the processor is caused to calculate the accumulated value of the apparent discharge energy of the current partial discharge of the electrical equipment based on the regression model and using the accumulated value as the index of risk assessment to assess the insulation state of the electrical equipment in the following manners:
finding a predicted value of apparent discharge energy corresponding to a current discharge pulse point of the electrical equipment in the regression model:
ADE(t)=ƒ(A₁′(t),A₂′(t), . . . ,A_{N-1}′(t)),
wherein A′ᵢ(t) denotes a normalized result of response amplitude of an i-th sensor under a discharge pulse signal at time t, and ADE(t) denotes a predicted value of the apparent discharge energy obtained from the discharge pulse signal at the time t; and
accumulating predicted values of the apparent discharge energy and time during a monitoring and early warning process to determine an insulation risk level:
$$Risk\_level = {\int }_{0}^{t} A D E ( dt ) ,$$
wherein ∫₀^{t} ADE(t)dt denotes integral of the apparent discharge energy from 0 to t;
in a case where Risk_level<α, determining that the electrical equipment has no discharge;
in a case where α≤Risk_level≤β, determining that a slight partial discharge occurs in the electrical equipment; and
in a case where Risk_level>β, determining that a serious discharge occurs in the electrical equipment; wherein a threshold α is set according to 120% of risk index under background noise of an operation site of the electrical equipment; and a threshold β is set according to a risk index at maximum temperature allowed under a rated operation state of the electrical equipment.

14. The system of claim 8, wherein the discharge types comprise corona discharge, creeping discharge, and floating potential discharge.

15. The system of claim 8, wherein the plurality of types of sensors comprise an optical sensor, an ultra-high frequency sensor, and an ultrasonic sensor.

16. The storage medium of claim 10, wherein the processor is caused to measure the partial discharge data of the electrical equipment using the plurality of types of sensors and performing clustering of the discharge types in the following manners:
in a case where a high-frequency current sensor is not used, using a total of N sensors of different types to collect the partial discharge data of the electrical equipment, and normalizing response amplitude Aᵢ of each sensor to obtain A′ᵢ:
$${A}_{i}^{′} = \frac{{A}_{i}}{{\sum }_{k = 1}^{N} {A}_{k}} ,$$
wherein Aᵢ denotes response amplitude of a sensor numbered i under an action of partial discharge pulse, and Σₖ₌₁^{N} Aₖ denotes a sum of response amplitudes of the N sensors; and
using a normalized result {A′₁, A′₂, . . . , A′_{N-1}} of response amplitude of previous (N−1) sensors as input, and performing support vector machine (SVM) clustering on the discharge types to establish a clustering area in (N−1) dimensional space.

17. The storage medium of claim 16, wherein the processor is caused to establish the regression model between the sensor response amplitude and the apparent discharge energy during the discharge development process based on the clustering result of the each discharge type in the following manners:
describing a relationship between (N−1) dimensional space constituted by {A′₁, A′₂, . . . , A′_{N-1}} and the apparent discharge energy using Gaussian process regression, wherein the Gaussian process ƒ(x) is described by a mean function m(x) and a covariance function k(x, x′) as:
ƒ(x)˜GP(m(x),k(x,x′)),
wherein the covariance function k(x, x′) is of a square exponential type:
$$k ( x , {x}^{′} ) = exp ( - \frac{\sqrt{{( x − {x}^{′} )}^{T} ( x − {x}^{′} )}}{2} ) ;$$
establishing the regression model based on the Gaussian process regression, wherein a parameter of the regression model is determined by a training data set, and the training data set is:
X=(x₁,x₂, . . . ,xₙ),Y=(y₁,y₂, . . . ,yₙ)^{T},
wherein
in the covariance function k(x, x′), when x takes xᵢ, xᵢ denotes a vector composed of response amplitude of a sensor under an action of an i-th discharge pulse: xᵢ=(A′₁, A′₂, . . . , A′_{N-1})^{T}, wherein i ranges from 1 to n, and n is an n-th discharge pulse;
when x takes xᵢ, x′ takes xⱼ, xⱼ denotes a vector of a same type as xᵢ, j ranges from 1 to n, and j is not equal to i;
x and x′ are independent variables corresponding to vectors composed of response amplitudes of sensors under an action of different discharge pulses, x and x′ are not equal in form;
when i ranges from 1 to n, yᵢ denotes apparent discharge energy measured by a high-frequency current sensor under the action of the i-th discharge pulse;
a random vector of prediction variable distribution of the training data set is generated as:
$$Y = f ( X ) + ε ∼ N ( μ ( X ) , K ( X , X ) + {σ}^{-} {I}_{n} ) ,$$
wherein joint distribution of a function value Y and an observation target value f* is expressed as:
$$[ \begin{matrix}Y \\ {f}_{*}\end{matrix} ] ∼ N ( [ \begin{matrix}μ ( X ) \\ μ ( {X}_{*} )\end{matrix} ] , \begin{matrix}K ( X , X ) + {σ}^{2} {I}_{n} & K ( X , {X}_{*} ) \\ K ( {X}_{*} , X ) & K ( {X}_{*} , {X}_{*} )\end{matrix} ) ,$$
wherein the observation target value f* is a predicted value of discharge energy to be predicted, and the predicted value of the discharge energy is an output of the regression model;
Iₙ denotes an n-order identity matrix whose diagonal elements are 1 and remaining elements are 0, and X_{*}=(x₁, x₂, . . . , xₙ, xₙ₊₁) is composed of all elements in the training data set X=(x₁, x₂, . . . , xₙ) and new observation data xₙ₊₁;
μ(X) is a mean vector of the training data set X, and an i-th component of μ(X) is an average of all elements in an i-th row of X;
μ(X_{*}) is a mean vector of X_{*}, and an i-th component of μ(X_{*}) is an average of all elements in an i-th row of X_{*};
ε is Gaussian noise, and the Gaussian noise ε obeys a normal distribution N(μ(X),K(X,X)+σ² Iₙ);
σ is a random error contained in a variance of the normal distribution N(μ(X),K(X,X)+σ²Iₙ), and the random error reduces an impact of a measurement error present in the training data set;
K(X,X) is a covariance matrix, and an element in an i-th row and a j-th column of the covariance matrix is obtained by taking a squared exponential kernel function of an i-th column element xᵢ of X and a j-th column element xⱼ of X:
$$k ( {x}_{i} {x}_{j} ) = exp ( - \frac{\sqrt{{( {x}_{i} − {x}_{j} )}^{T} ( {x}_{i} − {x}_{j} )}}{2} ) ;$$
an element in an i-th row and a j-th column of a covariance matrix K(X,X_{*}) is obtained by taking a squared exponential kernel function of an i-th column element xᵢ of X and a j-th column element xⱼ of X_{*};
an element in an i-th row and a j-th column of K(X_{*},X) is obtained by taking a squared exponential kernel function of an i-th column element xᵢ of X_{*} and a j-th column element xⱼ of X;
an element in an i-th row and a j-th column of K(X_{*},X_{*}) is obtained by taking a squared exponential kernel function of an i-th column element xᵢ of X_{*} and a j-th column element xⱼ of X_{*};
in a case where Y,X,X_{*} are known, conditional distribution of ƒ_{*} is normal distribution of mean μ_{*} and variance Σ_{*}:
P(ƒ_{*}|Y,X,X_{*})˜N(μ_{*},Σ_{*})
wherein the mean μ_{*} and variance Σ_{*} are:
$${μ}_{⋆} = K ( {X}_{⋆} , X ) {( K ( X , X ) + {σ}^{2} {I}_{n} )}^{− 1} ( Y - μ ( X ) ) + μ ( {X}_{⋆} )$$
$${\sum }_{⋆} = K ( {X}_{⋆} , {X}_{⋆} ) − K ( {X}_{⋆} , X ) {( K ( X , X ) + {σ}^{2} {I}_{n} )}^{− 1} K ( X , {X}_{⋆} ) ;$$
and
obtaining mean and variance corresponding to the new observation data xₙ₊₁ from the conditional distribution of ƒ_{*}, to obtain a predicted value of the apparent discharge energy, that is, the observation target value ƒ_{*}.

18. The storage medium of claim 10, wherein the processor is caused to calculate the accumulated value of the apparent discharge energy of the current partial discharge of the electrical equipment based on the regression model and using the accumulated value as the index of risk assessment to assess the insulation state of the electrical equipment in the following manners:
finding a predicted value of apparent discharge energy corresponding to a current discharge pulse point of the electrical equipment in the regression model:
ADE(t)=ƒ(A₁′(t),A₂′(t), . . . ,A_{N-1}(t)),
wherein A′ᵢ(t) denotes a normalized result of response amplitude of an i-th sensor under a discharge pulse signal at time t, and ADE(t) denotes a predicted value of the apparent discharge energy obtained from the discharge pulse signal at the time t; and
accumulating predicted values of the apparent discharge energy and time during a monitoring and early warning process to determine an insulation risk level:
$$Risk\_level = {\int }_{0}^{t} A D E ( dt ) ,$$
wherein ∫₀^{t} ADE(t)dt denotes integral of the apparent discharge energy from 0 to t;
in a case where Risk_level<α, determining that the electrical equipment has no discharge;
in a case where α≤Risk_level≤β, determining that a slight partial discharge occurs in the electrical equipment; and
in a case where Risk_level>β, determining that a serious discharge occurs in the electrical equipment; wherein a threshold α is set according to 120% of risk index under background noise of an operation site of the electrical equipment; and a threshold β is set according to a risk index at maximum temperature allowed under a rated operation state of the electrical equipment.

19. The storage medium of claim 10, wherein the discharge types comprise corona discharge, creeping discharge, and floating potential discharge.

20. The storage medium of claim 10, wherein the plurality of types of sensors comprise an optical sensor, an ultra-high frequency sensor, and an ultrasonic sensor.
